(19) United States
(12) Patent Application Publication
(10) Pub. No.: US 2026/0076203 A1
(43) Pub. Date: Mar. 12, 2026

(54) SEMICONDUCTOR PACKAGE SUBSTRATE

(71) Applicant: HAESUNG DS CO., LTD., Gyeongsangnam-do (KR)

(72) Inventors: Dong Jin YOON, Gyeongsangnam-do (KR); Sung Il KANG, Gyeongsangnam-do (KR)

(21) Appl. No.: 19/224,990

(22) Filed: Jun. 2, 2025

(30) Foreign Application Priority Data
Jul. 22, 2024 (KR) 10-2024-0096485

(51) Int. Cl. H01L 23/00; H01L 23/498

(52) U.S. Cl. CPC H10W 42/121; H10W 70/65

(57) ABSTRACT

A semiconductor package substrate includes a base substrate including a conductive material and having a first groove or first trench located in a bottom surface of the base substrate, a resin filled into the first groove or first trench, a first plating layer disposed on a top surface of the base substrate, and a second plating layer disposed on the bottom surface of the base substrate, wherein the base substrate includes a stress reducing portion configured to reduce stress.

### CROSS-REFERENCE TO RELATED APPLICATION

This application is based on and claims priority under 35 U.S.C. § 119 to Korean Patent Application No. 10-2024-0096485, filed on Jul. 22, 2024, in the Korean Intellectual Property Office, the disclosure of which is incorporated by reference herein in its entirety.

### BACKGROUND

### 1. Field

The disclosure relates to a device, and more particularly, to a semiconductor package substrate.

### 2. Description of the Related Art

Semiconductor devices are packaged and used in semiconductor package substrates, and the semiconductor package substrates used for such packaging have microcircuit patterns and/or I/O terminals. As semiconductor devices have more improved performance and/or become more highly integrated, and electronic devices using the semiconductor devices become smaller and have improved performance, microcircuit patterns of semiconductor package substrates become narrower and more complex.

A conventional method of manufacturing a semiconductor package substrate involves forming a through-hole by using a copper clad laminate with copper foil, plating an inner surface of the through-hole to electrically connect an upper copper foil to a lower copper foil, and patterning each of the upper copper foil and the lower copper foil by using a photoresist. However, the conventional method of manufacturing a semiconductor package substrate has a problem in that a manufacturing process is complicated and the precision is low.

Recently, a method of manufacturing a semiconductor package substrate by filling an insulating material into a conductive base substrate has been introduced in order to simplify a manufacturing process.

### SUMMARY

Provided is a semiconductor package substrate capable of controlling warpage. However, such a technical problem is merely an example and does not limit the scope of the disclosure.

Additional aspects will be set forth in part in the description which follows and, in part, will be apparent from the description, or may be learned by practice of the presented embodiments.

According to an aspect of the disclosure, a semiconductor package substrate includes a base substrate including a conductive material and having a first groove or a first trench located in a bottom surface thereof, a resin filled into the first groove or the first trench, a first plating layer disposed on a top surface of the base substrate, and a second plating layer disposed on the bottom surface of the base substrate, wherein the base substrate includes a stress reducing portion configured to reduce stress.

In the present embodiment, the stress reducing portion may be a slot.

In the present embodiment, the stress reducing portion may include a first stress reducing portion formed long in a first direction, and a second stress reducing portion formed long in a second direction different from the first direction.

In the present embodiment, a plurality of second stress reducing portions may be provided, wherein the plurality of second stress reducing portions are arranged within a length of the first stress reducing portion to be spaced apart from each other.

In the present embodiment, a plurality of stress reducing portions may be provided to be spaced apart from each other, wherein a thickness of the base substrate between adjacent stress reducing portions among the plurality of stress reducing portions is less than thicknesses of other portions of the base substrate.

In the present embodiment, the resin may be inserted into a portion of the base substrate disposed between the stress reducing portions.

According to another aspect of the disclosure, a semiconductor package substrate includes a base substrate including a conductive material and having a first groove or a first trench located in a bottom surface of the base substrate, a resin filled into the first groove or the first trench, and a plating layer disposed on the base substrate, wherein the base substrate includes a stress reducing portion configured to reduce stress.

### BRIEF DESCRIPTION OF THE DRAWINGS

The above and other aspects, features, and advantages of certain embodiments will be more apparent from the following description taken in conjunction with the accompanying drawings, in which:

FIG. 1 is a rear view schematically illustrating a semiconductor package substrate, according to an embodiment;

FIG. 2 is a cross-sectional view schematically illustrating a part of the semiconductor package substrate of FIG. 1;

FIGS. 3A to 3H are cross-sectional views schematically illustrating embodiments of an etching portion of FIG. 1;

FIG. 4 is a cross-sectional view schematically illustrating a stress reducing portion of FIG. 1;

FIGS. 5 to 12 are cross-sectional views schematically illustrating a method of manufacturing a semiconductor package substrate, according to an embodiment;

FIG. 13 is a cross-sectional view schematically illustrating a semiconductor package including a semiconductor package substrate, according to an embodiment; and

FIG. 14 is a cross-sectional view schematically illustrating a part of a semiconductor package substrate, according to another embodiment.

### DETAILED DESCRIPTION

Reference will now be made in detail to embodiments, examples of which are illustrated in the accompanying drawings, wherein like reference numerals refer to like elements throughout. In this regard, the present embodiments may have different forms and should not be construed as being limited to the descriptions set forth herein. Accordingly, the embodiments are merely described below, by referring to the figures, to explain aspects of the present description. As used herein, the term “and/or” includes any and all combinations of one or more of the associated listed items. Expressions such as “at least one of,” when preceding a list of elements, modify the entire list of elements and do not modify the individual elements of the list.

The disclosure will become apparent with reference to embodiments described below in detail in conjunction with the accompanying drawings. The disclosure may, however, be embodied in many different forms and should not be construed as limited to embodiments set forth herein; rather these embodiments are provided so that this disclosure will be thorough and complete, and will fully convey the scope of the disclosure to one of ordinary skill in the art, and the scope of the disclosure is defined only by the accompanying claims. The terms used herein are for the purpose of describing embodiments only and are not intended to limit the disclosure. As used herein, the singular forms “a,” “an,” and “the” are intended to include the plural forms as well, unless the context clearly indicates otherwise. It will be further understood that the terms “comprises” and/or “comprising” used herein specify the presence of stated elements, steps, operations, and/or devices, but do not preclude the presence or addition of one or more other elements, steps, operations, and/or devices. It will be understood that although the terms “first,” “second,” etc. may be used herein to describe various elements, these elements should not be limited by these terms. The terms are used only to distinguish one element from another.

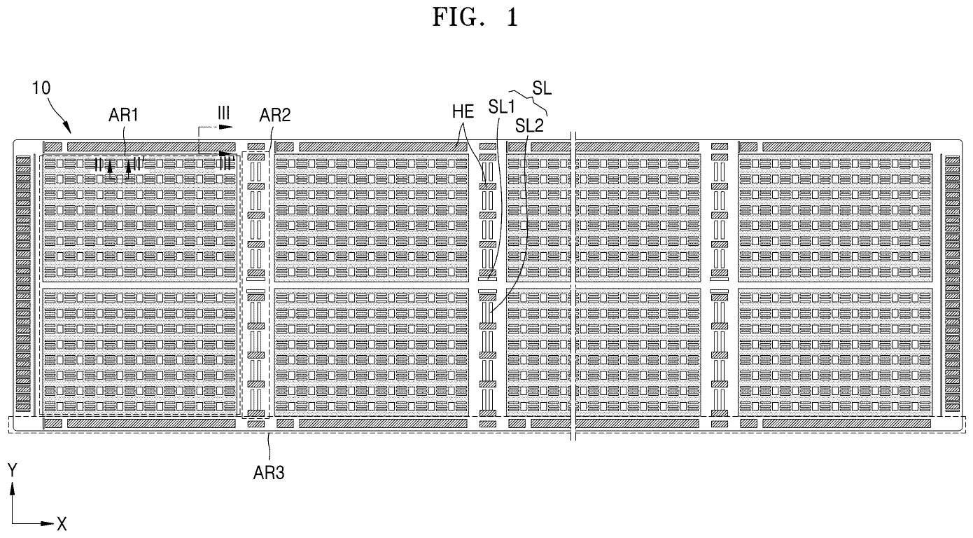

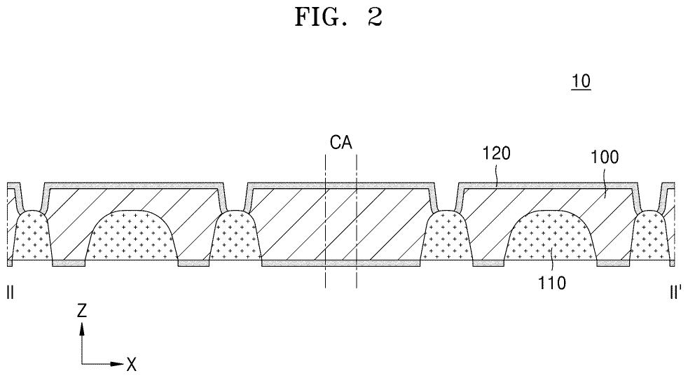

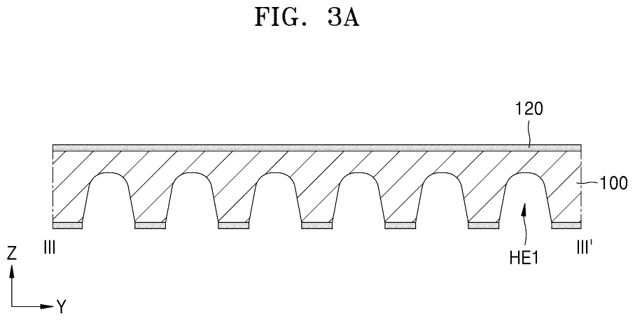

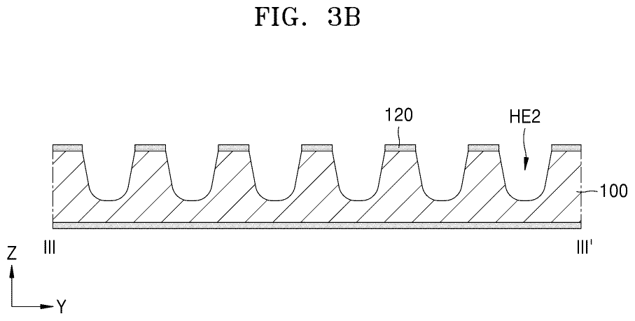

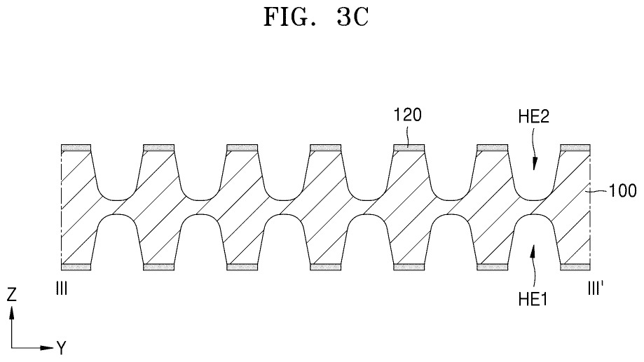

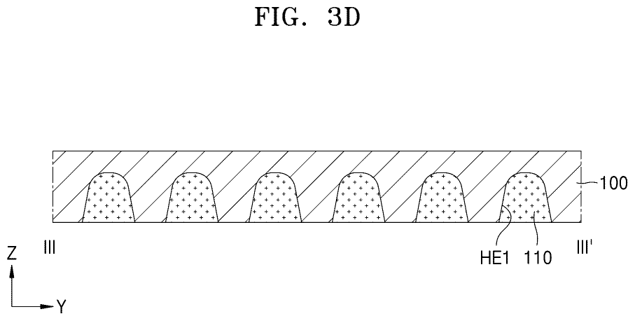

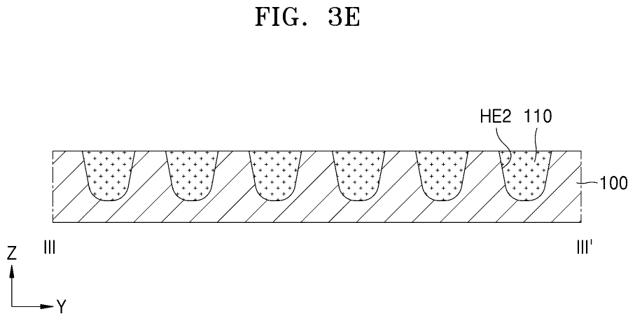

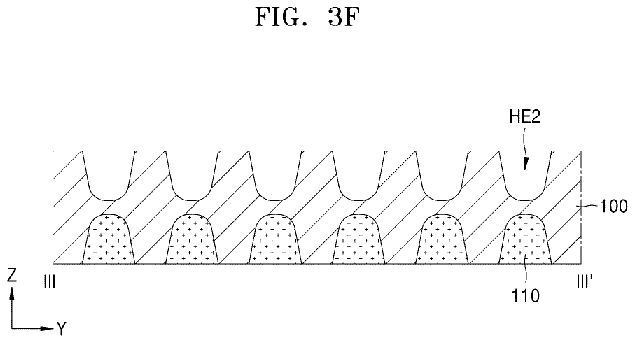

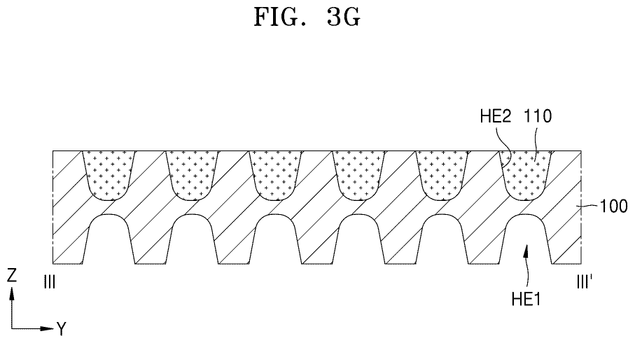

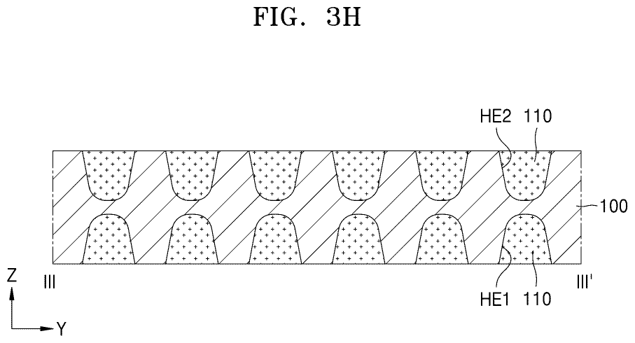

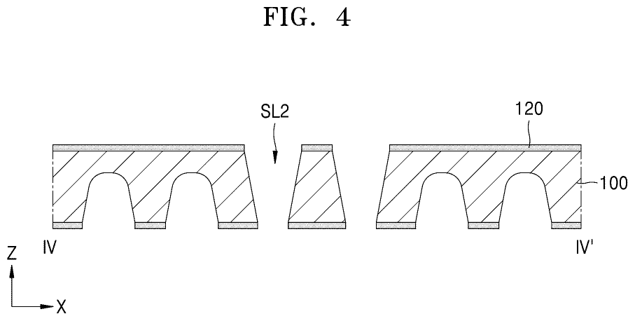

FIG. 1 is a rear view schematically illustrating a semiconductor package substrate, according to an embodiment. FIG. 2 is a cross-sectional view schematically illustrating a part of the semiconductor package substrate of FIG. 1. FIGS. 3A to 3H are cross-sectional views schematically illustrating embodiments of an etching portion of FIG. 1. FIG. 4 is a cross-sectional view schematically illustrating a stress reducing portion of FIG. 1. In this case, FIG. 2 is a cross-sectional view taken along line II-II′ of FIG. 1, FIGS. 3A to 3H are cross-sectional views taken along line III-III′ of FIG. 1, and FIG. 4 is a cross-sectional view taken along line IV-IV′ of FIG. 1.

Referring to FIGS. 1 to 4, a semiconductor package substrate 10 may include a base substrate 100, a resin 110, a plating layer 120, and a stress reducing portion SL.

The base substrate 100 may have a flat plate shape including an electrically conductive material. The electrically conductive material may include Fe, an Fe alloy such as Fe—Ni or Fe—Ni—Co, Cu, or a Cu alloy such as Cu—Sn, Cu—Zr, Cu—Fe, or Cu—Zn.

The base substrate 100 having a plate shape may have a top surface 100b and a bottom surface 100a opposite to each other. The stop surface 100b refers to a surface on which a semiconductor chip described below is to be mounted, and the bottom surface 100a is a rear surface and refers to a surface located opposite to the top surface 100b.

In an embodiment, a thickness of the base substrate 100 may be about 100 μm to about 500 μm, for example, about 185 μm to about 200 μm. The base substrate 100 may include at least one groove (not shown) and/or at least one through-hole (not shown). In this case, the at least one groove may be recessed from one surface of the base substrate 100, and the at least one through-hole may extend from one surface of the base substrate 100 to the other surface of the base substrate 100.

The base substrate 100 may be separated into multiple parts after a semiconductor chip (not shown) is mounted. In this case, the base substrate 100 may include a mounting area AR1 where each of a plurality of semiconductor chips is mounted. A plurality of mounting areas AR1 may be provided, and the plurality of mounting areas AR1 may be spaced apart from each other. Also, the base substrate 100 may include an intermediate area AR2 between the mounting area AR1 and the mounting area AR1, and a peripheral area AR3 disposed outside the mounting area AR1 and the intermediate area AR2.

The resin 110 may be disposed in at least one of the through-hole and the groove. When the resin 110 is disposed in the through-hole, the resin 110 may be disposed only in a part of the through-hole. The resin 110 disposed in the groove may completely fill the inside of the groove. A material of the resin 110 is not limited as long as the resin 110 is formed of an insulating material that is not electrically conductive. For example, the resin 110 may be a thermosetting resin that is polymerized and cured by heat treatment. The resin 110 electrically insulates between wiring patterns of the semiconductor package substrate later. The filling of the resin 110 may be performed by using a liquid material, may be performed by using a solid tape including a resin component, or may be performed by using powder including a resin component.

The plating layer 120 may be disposed on at least one of the top surface and the bottom surface of the base substrate 100. For convenience of explanation, the following will be described in detail assuming that the plating layer 120 is disposed on both the top surface and the bottom surface of the base substrate 100. For example, the plating layer 120 may include at least one of a first plating layer disposed on the top surface of the base substrate 100, and a second plating layer disposed on the bottom surface of the base substrate 100. The first plating layer and the second plating layer may be respectively disposed on the top surface and the bottom surface of the base substrate 100. Each of the first plating layer and the second plating layer may be plated by using, for example, Au, Pd, or NiPd. A method such as anti-tarnish or organic film coating such as organic solderability preservative (OSP) may be used on the bottom surface 100b of the base substrate 100.

The stress reducing portion SL may be disposed on the base substrate 100. At least one stress reducing portion SL may be provided. In this case, the at least one stress reducing portion SL may be a slot. That is, the stress reducing portion SL may be a long hole formed long on one side. For convenience of explanation, the following will be described in detail assuming that the stress reducing portion SL includes a first stress reducing portion SL1 and a second stress reducing portion SL2.

At least one of the first stress reducing portion SL1 and the second stress reducing portion SL2 may be a slot. In an embodiment, each of the first stress reducing portion SL1 and the second stress reducing portion SL2 may be a slot. In this case, a longitudinal direction of the first stress reducing portion SL1 and a longitudinal direction of the second stress reducing portion SL2 may be different from each other. For example, the first stress reducing portion SL1 may be formed long in a first direction, and the second stress reducing portion SL2 may be formed long in a second direction. In this case, the first direction and the second direction may not be parallel to each other and may form a certain angle. In particular, the first direction and the second direction may form a right angle with each other. Also, the first direction may correspond to a movement direction of the base substrate 100, and the second direction may be a direction perpendicular to the movement direction of the base substrate 100.

In this case, at least one of the first stress reducing portion SL1 and the second stress reducing portion SL2 may include a plurality of stress reducing portions. For example, a plurality of first stress reducing portions SL1 may be provided. At least one of the plurality of first stress reducing portions SL1 may be spaced apart from another of the plurality of first stress reducing portions SL1 in the first direction. Also, at least one of the plurality of first stress reducing portions SL1 may be spaced apart from another of the plurality of first stress reducing portions SL1 in the second direction. A plurality of second stress reducing portions SL2 may be provided. In this case, one of the plurality of second stress reducing portions SL2 may be spaced apart from another of the plurality of second stress reducing portions SL2 in the first direction. Also, one of the plurality of second stress reducing portions SL2 may be spaced apart from another of the plurality of second stress reducing portions SL2 in the second direction. In this case, the second stress reducing portion SL2 may be disposed between adjacent first stress reducing portions SL1. In another embodiment, the first stress reducing portion SL1 may be disposed between adjacent second stress reducing portions SL2. In particular, the first stress reducing portion SL1 and the second stress reducing portion SL2 may be arranged symmetrically with respect to an arbitrary center line passing through the center of a planar shape of the base substrate 100 while being parallel to a longitudinal direction of the base substrate 100. For example, two first stress reducing portions SL1 may be disposed at a central portion of the planar shape of the base substrate 100 based on the center line, and the second stress reducing portion SL2 may be arranged in a direction away from each first stress reducing portion SL1.

The second stress reducing portions SL adjacent to each other and spaced apart from each other may be arranged within a length of the first stress reducing portion SL1. That is, a distance between an outermost edges of the second stress reducing portions SL2 adjacent to each other may be less than a length of the first stress reducing portion SL1.

The stress reducing portion SL may be formed from the top surface to the bottom surface of the base substrate 100 or may be formed from the bottom surface to the top surface of the base substrate 100. For convenience of explanation, the following will be described in detail assuming that the stress reducing portion SL is formed from the top surface to the bottom surface of the base substrate 100 as shown in FIG. 4.

An etching portion HE may be formed between adjacent stress stringing portions SL and/or at an edge portion of the base substrate 100. The etching portion HE may have a thickness less than a maximum thickness of the base substrate 100. A plurality of etching portions HE may be provided, and the plurality of etching portions HE may be spaced apart from each other.

The etching portion HE may include at least one etching groove recessed from the top surface and/or the bottom surface of the base substrate 100. For example, as shown in FIGS. 3A and 3D, the etching portion HE may include a first etching groove HE1 that is disposed in the bottom surface of the base substrate 100 so as to extend from the bottom surface (not shown) of the base substrate 100 to the top surface (not shown) of the base substrate 100. In another embodiment, as shown in FIGS. 3B and 3E, the etching portion HE may include a second etching groove HE2 disposed in the top surface of the base substrate 100 so as to extend from the top surface of the base substrate to the bottom surface of the base substrate 100. In another embodiment, as shown in FIGS. 3C and 3F to 3H, the etching portion HE may include the first etching groove HE1 and the second etching groove HE2 disposed in both the top surface and the bottom surface of the base substrate 100.

The etching portion HE may be a groove. Also, the etching portion HE may have an uneven shape. For example, the etching portion HE may have a comb-patterned shape. That is, the etching portion HE may be formed so that the etching grooves are spaced apart from each other. In this case, a longitudinal direction of the etching groove may be diagonal to a transfer direction of the base substrate 100.

As shown in FIGS. 3D to 3H, the resin 110 may be disposed in at least a part of the inside of the etching portion HE. In this case, the resin 110 may be disposed to a depth of the etching portion HE to maintain the same level as the top surface and/or the bottom surface of the base substrate 100. Also, the resin 110 may be disposed inside the etching portion HE so as to be disposed between adjacent first stress reducing portions SL1 and/or second stress reducing portions SL2.

In this case, as shown in FIGS. 3D to 3H, the plating layer 120 may not be disposed on the base substrate 100. However, the disclosure is not limited thereto, and although not shown in FIGS. 3D to 3H, the plating layer 120 may be disposed on the base substrate 100 as shown in FIGS. 3A to 3C.

The semiconductor package substrate 10 may be formed by using a reel-to-reel process. In this case, warpage of the semiconductor package substrate 10 may occur due to a coefficient of thermal expansion between the base substrate 100 and the resin 110. Also, when the resin 110 is disposed on the base substrate 100 and a part of the resin 110 is removed by grinding, stress may remain on the base substrate 100. In this case, the stress reducing portion SL may reduce warpage of the semiconductor package substrate 10 occurring during the manufacture of the semiconductor package substrate 10. That is, when stress occurs in a portion of the semiconductor package substrate 10 during the manufacture of the semiconductor package substrate 10, the stress reducing portion SL may reduce warpage of the entire semiconductor package substrate 10 by accepting deformation of the semiconductor package substrate 10 to some extent.

In particular, because the stress reducing portion SL is formed as a slot, connection between the base substrates 100 disposed on both sides of and above and below the stress reducing portion SL may be cut off, thereby partially preventing stress occurring in a portion of the base substrate 100 from being transferred to another portion of the base substrate 100.

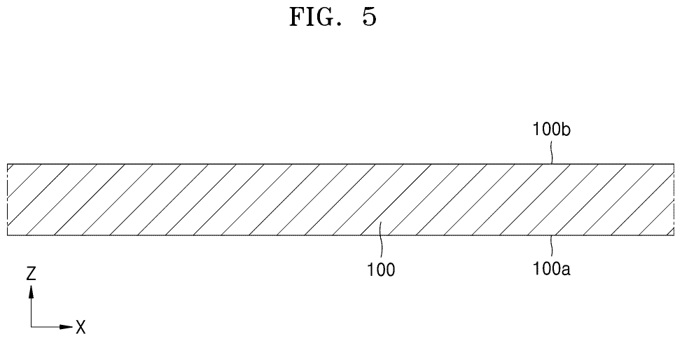

FIGS. 5 to 12 are cross-sectional views schematically illustrating a method of manufacturing a semiconductor package substrate, according to an embodiment.

Referring to FIGS. 5 to 12, first, as shown in FIG. 5, the base substrate 100 formed of a conductive material is prepared. The base substrate 100 may have a flat plate shape including an electrically conductive material. The electrically conductive material may include Fe, an Fe alloy such as Fe—Ni or Fe—Ni—Co, Cu, or a Cu alloy such as Cu—Sn, Cu—Zr, Cu—Fe, or Cu—Zn. The base substrate 100 having a plate shape may have the top surface 100b and the bottom surface 100a opposite to each other.

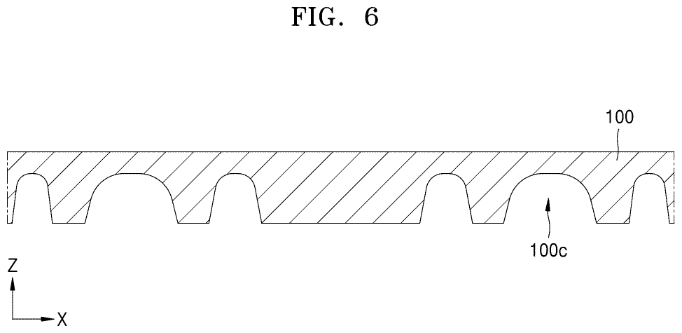

Next, as shown in FIG. 6, a first groove or a first trench 100c is formed in the bottom surface 100a of the base substrate 100. The first groove or the first trench 100c means that the first groove or the first trench 100c does not completely pass through the base substrate 100. Although not shown in the cross-sectional view of FIG. 6, a portion of the bottom surface 100a of the base substrate 100 other than the first groove or the first trench 100c may be a wiring pattern that extends in one direction or meanders in a plan view.

In order to form the first groove or the first trench 100c, a dry film resist (DFR) formed of a photosensitive material is laminated on the bottom surface 100a of the base substrate 100, and only a portion of the base substrate 100 where the first groove or the first trench 100c is to be formed is exposed through processes such as exposure and development. Next, a portion of the bottom surface 100a of the base substrate 100 not covered by the DFR may be etched by using an etching solution such as copper chloride or iron chloride, to form the first groove or the first trench 100c formed in the bottom surface 100a without passing through the base substrate 100 as shown in FIG. 6.

A portion remaining on the bottom surface 100a of the base substrate 100 that is not removed, that is, a portion other than the first groove or the first trench 100c, may function as a wiring pattern later. Accordingly, when the first groove or the first trench 100c is formed in the bottom surface 100a of the base substrate 100, a width of a portion between adjacent grooves or trenches may be preferably about 20 μm to about 30 μm, which is a width of a typical wiring pattern.

When the first groove or the first trench 100c is formed in the bottom surface 100a of the base substrate 100 as shown in FIG. 6, a depth of the first groove or the first trench 100c may be preferably about 80% to about 90% of a thickness of the base substrate 100. For example, a remaining thickness of a portion where the first groove or the first trench 100c of the base substrate 100 is formed may be about 10 μm to about 40 μm.

When a depth of the first groove or the first trench 100c is greater than this, handling of the base substrate 100 or the semiconductor substrate may not be easy during a semiconductor package substrate manufacturing process or a subsequent packaging process. Also, when a depth of the first groove or the first trench 100c is greater than this, in some cases, a through-hole passing through the bottom surface 100a and the top surface 100b of the base substrate 100 may be formed due to a tolerance or the like when forming the first groove or the first trench 100c. When a depth of the first groove or the first trench 100c is less than this, a subsequent process may not be easy when manufacturing the semiconductor package substrate or the semiconductor package substrate finally manufactured may be excessively thin.

When the first groove or the first trench 100c is formed, a separate first etching groove HE1 may also be formed in the base substrate 100. In this case, the first etching groove HE1 may have a shape that is the same as or similar to that of the first groove or the first trench 100c.

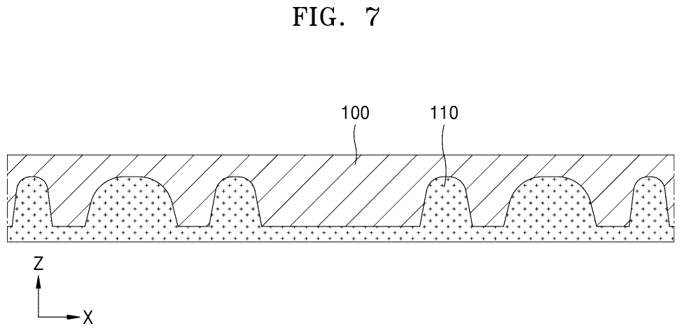

Next, as shown in FIG. 7, the first groove or the first trench 100c of the base substrate 100 is filled with the resin 110. In this case, the resin 110 may also be disposed inside the first etching groove HE1.

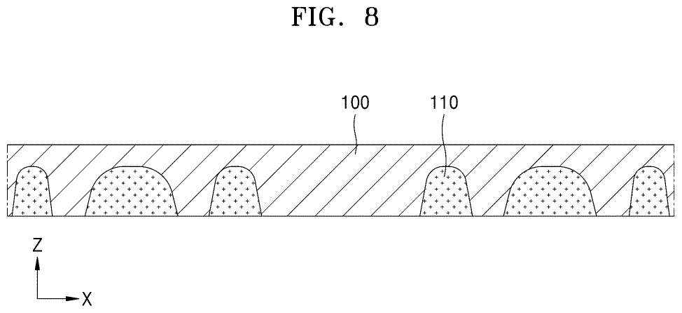

When the resin 110 is filled, as shown in FIG. 7, the resin 110 may not only fill the first groove or the first trench 100c of the base substrate 100, but may also cover at least a part of the bottom surface 100a of the base substrate 100. When the resin 110 is over-applied in this case, the over-applied resin 110 may be removed by using mechanical processing such as brushing, grinding, or polishing or may be removed by using chemical resin etching so that the resin 110 is located only in the first groove or the first trench 100c of the base substrate 100 as shown in FIG. 8.

When the resin 110 is filled, instead of over-filling as shown in FIG. 7, it may be considered to fill only the first groove or the first trench 100c of the base substrate 100 as shown in FIG. 8. In this case, the resin 110 may also be disposed inside the first etching groove HE1. However, in this case, there is a problem that the first groove or the first trench 100c of the base substrate 100 may not be appropriately filled with the resin 110.

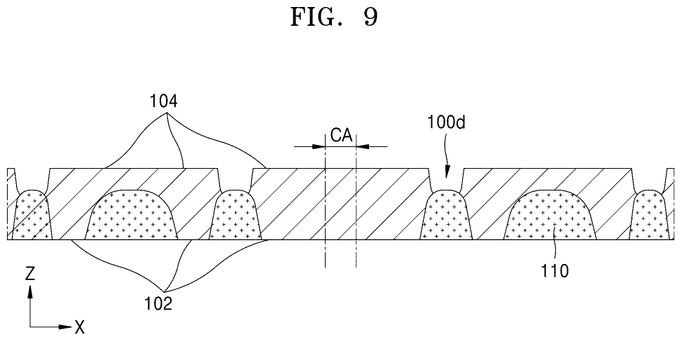

Next, the top surface 100b of the base substrate 100 is etched to form a portion 100d through which the resin 110 filing the first groove or the first trench 100c is exposed as shown in FIG. 9. The top surface 100b of the base substrate 100 may be etched in various ways. For example, a DFR formed of a photosensitive material is laminated on the top surface 100b of the base substrate 100, and only a portion of the top surface 100b of the base substrate 100 to be etched is exposed through processes such as exposure and development. Next, a portion of the top surface 100b of the base substrate 100 not covered by the DFR may be etched by using an etching solution such as copper chloride or iron chloride to expose at least a part of the resin 110 on the top surface 100b of the base substrate 100 as shown in FIG. 9.

In this case, the stress reducing portion SL may be formed in the top surface 100b of the base substrate 100. In this case, the stress reducing portion SL may be formed by passing through the base substrate 100 from the top surface 100b to the bottom surface 100a of the base substrate 100. In this case, a process for the stress reducing portion SL may be performed simultaneously a process of exposing the resin 110 on the top surface 100b of the base substrate 100. In this case, the stress reducing portion SL may be formed by spraying the etching solution to a portion where the stress reducing portion SL is to be formed for a longer time. Also, a process for the stress reducing portion SL may be performed after a process of exposing the resin 110 on the top surface 100b of the base substrate 100 is completed. In this case, the DFR may be covered to the remaining portion other than the portion the stress reducing portion SL is to be formed and the etching solution may be supplied. Also, the second etching groove HE2 may also be formed in the top surface 100b of the base substrate 100. In this case, the resin 110 may be disposed inside the second etching groove HE2 through a separate process.

Only one or both of the first etching groove HE1 and the second etching groove HE2 may be provided. In this case, the first etching groove HE1 and the second etching groove HE2 may be disposed on the same portion of the base substrate 100 so as to overlap each other, or may be disposed on different portions of the base substrate 100 so as not to overlap each other.

According to the above process, as shown in FIG. 9, a wiring pattern 102 between the resins 110 is formed even on the bottom surface 100a of the base substrate 100, and a wiring pattern 104 between the resins 110 is formed even on the top surface 100b of the base substrate 100. In the case of the semiconductor package substrate, the wiring pattern 104 on the top surface 100b and the wiring pattern 102 on the bottom surface 100a are electrically connected, and thus, conductive layer patterning of the top surface 100b and conductive layer patterning of the bottom surface 100a should be performed in a preset manner

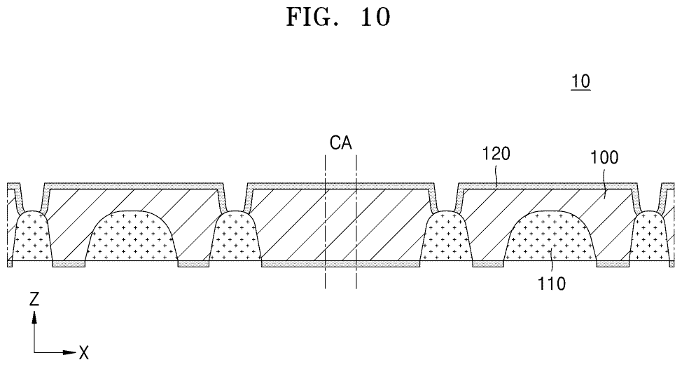

Next, as shown in FIG. 10, the plating layer 120 may be formed on at least a part of the remaining portion of the base substrate 100. When necessary, the plating layer 120 may be formed even on the top surface 100b, the bottom surface 100a, and an inner surface of the first groove or the first trench 100c of the base substrate 100 excluding the resin 110. The plating layer 120 may be plated by using, for example, Au, Pd, or NiPd Au-Alloy. A method such as anti-tarnish or organic film coating such as organic solderability preservative (OSP) may be used on the top surface 100b of the base substrate 100.

Before the resin 110 is filled in the first groove or the first trench 100c of the base substrate 100, an inner surface of the first groove or the first trench 100c may be roughened. Accordingly, an adhesive force between the resin 110 and the base substrate 100 may be dramatically increased. Plasma treatment, ultraviolet treatment, or a hydrogen peroxide sulfuric acid-based solution may be used to roughen the inner surface of the first groove or the first trench 100c of the base substrate 100, and in this case, a roughness of the inner surface of the first groove or the first trench 100c of the base substrate 100 may be 150 nm or more.

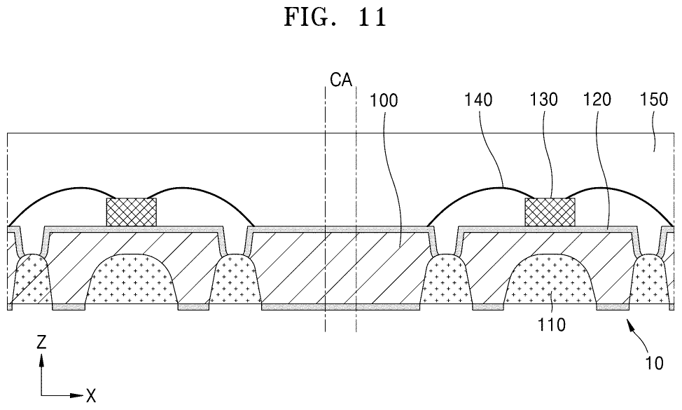

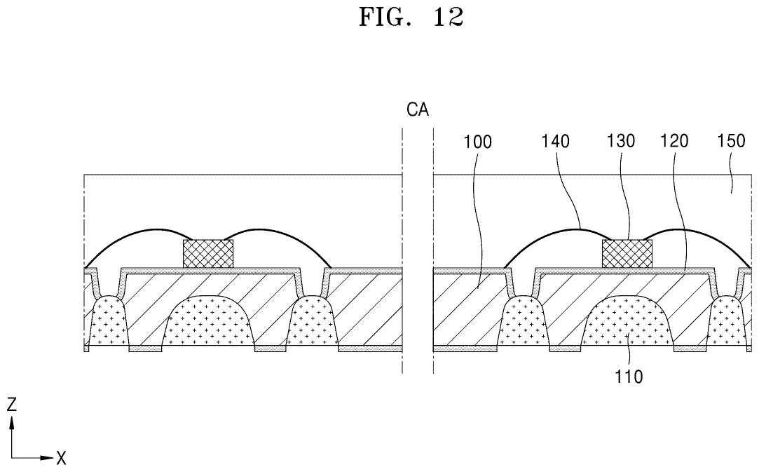

The semiconductor package substrate 10 manufactured as described above may be separated from each other by cutting a cutting area CA. For example, a portion between the mounting area AR1 and the intermediate area AR2 and between the mounting area AR1 and the peripheral area AR3 shown in FIG. 1 may be cut. Also, the mounting area AR1 may be cut into a plurality of parts. The semiconductor package substrate 10 may be cut after the manufacture of the semiconductor package substrate 10 is completed, or may be cut after a semiconductor chip 130 is mounted on the semiconductor package substrate 10. In another embodiment, as shown in FIGS. 11 and 12, the semiconductor chip 130 may be mounted on the semiconductor package substrate 10, a wire 140 may be formed, a molding layer 150 may be formed, and then the molding layer 150 and the semiconductor package substrate 10 may be cut.

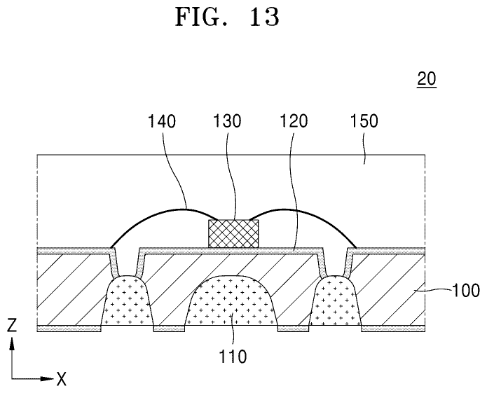

FIG. 13 is a cross-sectional view schematically illustrating a semiconductor package including a semiconductor package substrate, according to an embodiment.

Referring to FIG. 13, the semiconductor chip 130 is mounted on the base substrate 100 and the plating layer 120 of the semiconductor package substrate. In this case, the resin 110 may be inserted into a part of the base substrate 100. The semiconductor chip 130 may be mounted on a flat portion of a top surface of the semiconductor package substrate, and the semiconductor chip 130 may be electrically and physically connected to a lead of the base substrate 100 by the wire 140. The wire 140 may be connected to the semiconductor chip 130 and the lead by using wire bonding. One side of the wire 140 is attached to the lead, and the other side of the wire 140 is connected to the semiconductor chip 130.

The molding layer 150 may be formed on the semiconductor chip 130 mounted on the semiconductor package substrate. The molding layer 150 may seal the semiconductor chip 130 from the outside, and the molding layer 150 may be formed in a single molding structure, a double molding structure, or a triple or more molding structure. The molding layer 150 may be formed by curing the resin 110, and may include at least one of, for example, a fluorescent material and a light diffusing material. When necessary, a light-transmitting material that does not include a fluorescent material or a light diffusing material may be used.

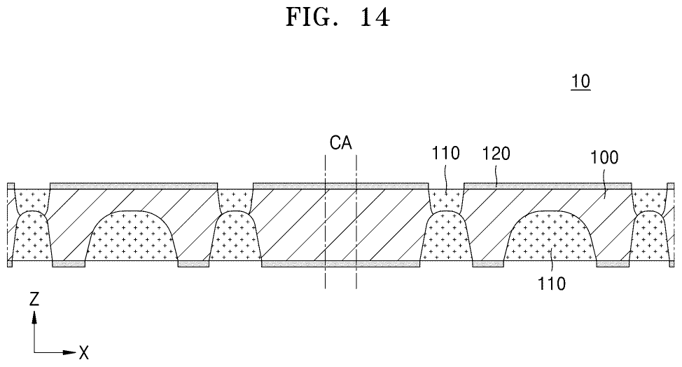

FIG. 14 is a cross-sectional view schematically illustrating a part of a semiconductor package substrate, according to another embodiment.

Referring to FIG. 14, the semiconductor package substrate 10 may include the base substrate 100, the resin 110, the plating layer 120, and a protrusion (not shown). In this case, the base substrate 100, the plating layer 120, and the protrusion are the same as or similar to those described with reference to FIGS. 1 to 3, and thus, a detailed description thereof will be omitted.

The resin 110 may be disposed in at least one of the through-hole and the groove. In this case, the resin 110 may fill the entire through-hole. In this case, the resin may be formed simultaneously or sequentially on the bottom surface and the top surface of the base substrate 100 as described above. In this case, a method of disposing the resin 110 in the through-hole is the same as or similar to that described above, and thus, a detailed description thereof will be omitted.

Accordingly, because the resin 110 completely fills the inside of the through-hole, flexibility of the semiconductor package substrate 10 may be provided and insulation between the base substrates 100 spaced apart from each other may be effectively provided.

According to embodiments, warpage of a semiconductor package substrate may be controlled. According to embodiments, after a semiconductor chip is mounted on the semiconductor package substrate, separation of the semiconductor chip from the semiconductor package substrate may be reduced.

It should be understood that embodiments described herein should be considered in a descriptive sense only and not for purposes of limitation. Descriptions of features or aspects within each embodiment should typically be considered as available for other similar features or aspects in other embodiments. While one or more embodiments have been described with reference to the figures, it will be understood by one of ordinary skill in the art that various changes in form and details may be made therein without departing from the spirit and scope of the disclosure as defined by the following claims.

What is claimed is:

1. A semiconductor package substrate comprising:
a base substrate comprising a conductive material and having a first groove or first trench located in a bottom surface thereof;
a resin filled into the first groove or first trench;
a first plating layer disposed on a top surface of the base substrate; and
a second plating layer disposed on the bottom surface of the base substrate,
wherein the base substrate comprises a stress reducing portion configured to reduce stress.

2. The semiconductor package substrate of claim 1, wherein the stress reducing portion is a slot.

3. The semiconductor package substrate of claim 1, wherein the stress reducing portion comprises:
a first stress reducing portion formed long in a first direction; and
a second stress reducing portion formed long in a second direction different from the first direction.

4. The semiconductor package substrate of claim 3, wherein a plurality of second stress reducing portions are provided,
wherein the plurality of second stress reducing portions are arranged within a length of the first stress reducing portion to be spaced apart from each other.

5. The semiconductor package substrate of claim 1, wherein a plurality of stress reducing portions are provided to be spaced apart from each other,
wherein a thickness of the base substrate between adjacent stress reducing portions among the plurality of stress reducing portions is less than thicknesses of other portions of the base substrate.

6. The semiconductor package substrate of claim 5, wherein the resin is inserted into a portion of the base substrate disposed between the stress reducing portions.

7. A semiconductor package substrate comprising:
a base substrate comprising a conductive material and having a first groove or first trench located in a bottom surface of the base substrate;
a resin filled into the first groove or first trench; and
a plating layer disposed on the base substrate,
wherein the base substrate comprises a stress reducing portion configured to reduce stress.
